(19) United States
(12) Patent Application Publication
(10) Pub. No.: US 2019/0256964 A1
(43) Pub. Date: Aug. 22, 2019

(54) EVAPORATION DEVICE AND MANUFACTURING APPARATUS OF DISPLAY DEVICE

(71) Applicant: BOE TECHNOLOGY GROUP CO., LTD., Beijing (CN)

(72) Inventor: Xiaobo DU, Beijing (CN)

(73) Assignee: BOE TECHNOLOGY GROUP CO., LTD., Beijing (CN)

(21) Appl. No.: 16/080,454

(22) PCT Filed: Jan. 8, 2018
(86) PCT No.: PCT/CN2018/071775

§ 371 Date: Aug. 28, 2018

(30) Foreign Application Priority Data
May 11, 2017 (CN) 201710331390.4

(51) Int. Cl. C23C 14/04; C23C 14/24

(52) U.S. Cl. CPC C23C 14/042; C23C 14/24

(57) ABSTRACT

An evaporation device and a manufacturing apparatus of a display device are disclosed, the evaporation device is configured to evaporate a substrate, and a side of the substrate is provided with a mask. The evaporation device includes a magnetic adsorption layer and a thermosensitive layer at a side of the magnetic adsorption layer, wherein the thermosensitive layer is located between the magnetic adsorption layer and a side of the substrate far away from the mask, and the thermosensitive layer is configured to adjust a distance between the mask and the magnetic adsorption layer.

The present invention claims the benefits of Chinese patent application No. 201710331390.4, which was filed with the SIPO on May 11, 2017 and is fully incorporated herein by reference as part of this application.

### TECHNICAL FIELD

At least one embodiment of the present disclosure provides an evaporation device and a manufacturing apparatus of a display device.

### BACKGROUND

Vacuum evaporation has been widely applied in a manufacturing process of a display device. However, when a mask used for vacuum evaporation is mounted on a substrate to be processed, a wrinkle may be occurred on part of area of the mask, and may result in that the mask is difficult to be completely attached onto the substrate during an evaporation process, which affects an evaporation precision and hence leads to problems in a display product as manufactured such as failed display.

### SUMMARY

At least one embodiment of the present disclosure provides an evaporation device for evaporating a substrate, a side of the substrate is provided with a mask, and the evaporation device includes: a magnetic adsorption layer; and a thermosensitive layer located at a side of the magnetic adsorption layer, wherein the thermosensitive layer is located between the magnetic adsorption layer and a side of the substrate far away from the mask, and the thermosensitive layer is configured to adjust a distance between the mask and the magnetic adsorption layer.

For example, in the evaporation device provided by at least one embodiment of the present disclosure, a range of linear expansion coefficient of the thermosensitive layer includes about 10⁻⁵-10⁻³ m/degree.

For example, in the evaporation device provided by at least one embodiment of the present disclosure, in a direction perpendicular to a plane of the magnetic adsorption layer, a thickness range of the thermosensitive layer includes about 1 mm˜10 cm.

For example, in the evaporation device provided by at least one embodiment of the present disclosure, the magnetic adsorption layer includes a plurality of magnetic adsorption units arranged in an array.

For example, in the evaporation device provided by at least one embodiment of the present disclosure, each of the magnetic adsorption units is mounted through an elastic component.

For example, in the evaporation device provided by at least one embodiment of the present disclosure, the thermosensitive layer includes a plurality of thermosensitive units arranged in an array, and each of the thermosensitive units is corresponding to one or more of the magnetic adsorption units.

For example, the evaporation device provided by at least one embodiment of the present disclosure further includes a cooling layer located at a side of the magnetic adsorption layer facing the thermosensitive layer.

For example, in the evaporation device provided by at least one embodiment of the present disclosure, one side of the cooling layer is located on a side of the thermosensitive layer far away from the magnetic adsorption layer, and the other side of the cooling layer is mounted with the substrate to be evaporated.

For example, the evaporation device provided by at least one embodiment of the present disclosure further includes: a limiting layer configured to limit the magnetic adsorption layer; wherein the limiting layer is a flexible layer, and the limiting layer is located between the thermosensitive layer and the magnetic adsorption layer.

For example, in the evaporation device provided by at least one embodiment of the present disclosure, the cooling layer is located between the magnetic adsorption layer and the thermosensitive layer, and the cooling layer is a flexible cooling layer.

For example, in the evaporation device provided by at least one embodiment of the present disclosure, a surface of the cooling layer far away from the thermosensitive layer is provided with a recess configured to limit the magnetic adsorption layer.

For example, the evaporation device provided by at least one embodiment of the present disclosure further includes an evaporation source, the evaporation source is located at a side of the thermosensitive layer far away from the magnetic adsorption layer and is spaced from the thermosensitive layer by a predetermined distance, wherein the evaporation source is configured to receive a material to be evaporated.

For example, the evaporation device provided by at least one embodiment of the present disclosure further includes a mounting part, wherein the mounting part is located between the thermosensitive layer and the evaporation source and is configured to allow the substrate and the mask to be mounted thereon.

At least one embodiment of the present disclosure provides a manufacturing apparatus of a display device, including the evaporation device according to any one of the embodiments above.

During an evaporation process of a substrate, when a mask for evaporating the substrate generates a wrinkle in a certain area, the evaporation device provided by at least one embodiment of the present disclosure can change a temperature of a thermosensitive layer in this area so that the thermosensitive layer can adjust its thickness according to a change in temperature so as to reduce a distance between a magnetic adsorption layer in this area and the mask; in this way, any issue attributed to the wrinkle on the mask is eliminated and an evaporation yield of the substrate is improved.

### BRIEF DESCRIPTION OF THE DRAWINGS

Hereinafter, the drawings accompanying embodiments of the present disclosure are simply introduced in order to more clearly explain technical solution(s) of the embodiments of the present disclosure. Obviously, the described drawings below are merely related to some of the embodiments of the present disclosure without constituting any limitation thereto.

FIG. 1 is a structural diagram illustrating an evaporation device provided by an embodiment of the present disclosure;

FIGS. 2A-2D are process diagrams illustrating a working principle of the evaporation device illustrated in FIG. 1;

FIG. 3 is a cross-sectional view illustrating another evaporation device provided by an embodiment of the present disclosure;

FIG. 4 is a cross-sectional view illustrating another evaporation device provided by an embodiment of the present disclosure;

FIG. 5 is a cross-sectional view illustrating another evaporation device provided by an embodiment of the present disclosure;

FIG. 6 is a cross-sectional view illustrating another evaporation device provided by an embodiment of the present disclosure;

FIG. 7 is a cross-sectional view illustrating another evaporation device provided by an embodiment of the present disclosure;

FIG. 8 is a cross-sectional view illustrating another evaporation device provided by an embodiment of the present disclosure; and

FIGS. 9A-9C are process diagrams illustrating an evaporation method of an evaporation device provided by an embodiment of the present disclosure.

### REFERENCE NUMERALS

1—vacuum evaporation chamber; 2—supporting part; 100—magnetic adsorption layer; 110—magnetic adsorption unit; 120—elastic component; 200—thermosensitive layer; 210—thermosensitive unit; 300—substrate; 400—mask; 500—cooling layer; 510—recess; 600—evaporation source; 700—limiting layer; 800—mounting part.

### DETAILED DESCRIPTION

In order to make objects, technical details and advantages of the embodiments of the invention apparent, technical solutions according to the embodiments of the present invention will be described clearly and completely as below in conjunction with the accompanying drawings of embodiments of the present invention. It is to be understood that the described embodiments are only a part of but not all of exemplary embodiments of the present invention. Based on the described embodiments of the present invention, various other embodiments can be obtained by those of ordinary skill in the art without creative labor and those embodiments shall fall into the protection scope of the present invention.

Unless otherwise defined, all the technical and scientific terms used herein have the same meanings as commonly understood by one of ordinary skill in the art to which the present invention belongs. The terms, such as “first,” “second,” or the like, which are used in the description and the claims of the present application, are not intended to indicate any sequence, amount or importance, but for distinguishing various components. Also, the terms, such as “a/an,” “one,” or the like, are not intended to limit the amount, but for indicating the existence of at least one. The terms, such as “comprise/comprising,” “include/including,” or the like are intended to specify that the elements or the objects stated before these terms encompass the elements or the objects and equivalents thereof listed after these terms, but not preclude other elements or objects. The terms, such as “connect/connecting/connected,” “couple/coupling/coupled” or the like, are not intended to define a physical connection or mechanical connection, but may include an electrical connection/coupling, directly or indirectly. The terms, “on,” “under,” “left,” “right,” or the like are only used to indicate relative position relationship, and when the position of the object which is described is changed, the relative position relationship may be changed accordingly.

At least one embodiment of the present disclosure provides an evaporation device and a manufacturing apparatus of a display device. The evaporation device includes a magnetic adsorption layer and a thermosensitive layer. One side of the thermosensitive layer is stacked on the magnetic adsorption layer, and the other side of the thermosensitive layer far away from the magnetic adsorption layer is configured to face towards a substrate to be evaporated. During an evaporation process, the evaporation device at least can solve the problem of evaporation failure caused by a mask which cannot be completely attached onto the substrate.

The magnetic adsorption layer allows the mask for evaporation to be attached onto the substrate. In the evaporation process, an evaporation material releases heat during depositing, and when a wrinkle is generated between the mask and the substrate, for example, the wrinkle is occurred in a first area, a portion of the mask in the first area may be spaced from the substrate by a distance so that a temperature of a portion of the thermosensitive layer in the first area is lower than that in other areas; in this way, a thickness of the portion of the thermosensitive layer in the first area is reduced, which decreases the distance between a portion of the magnetic adsorption layer in the first area and the portion of the mask in the first area; correspondingly, a magnetic adsorption force between the portion of the magnetic adsorption layer in the first area and the portion of the mask in the first area is increased to allow the portion of the mask in the first area to be attached onto the substrate. As above, the evaporation device provided by at least one embodiment of the present disclosure can adjust the distance between the magnetic adsorption layer and the mask, for example, in a real-time and automatic way, so as to mitigate or eliminate the occurrence of wrinkle on the mask, and improve the evaporation precision of the evaporation device with respect to the substrate.

Hereinafter, an evaporation device and a manufacturing apparatus of a display device provided by at least one embodiment of the present disclosure will be described in more details with reference to the accompanying drawings.

At least one embodiment of the present disclosure provides an evaporation device for evaporating a substrate, and a side of the substrate is provided with a mask. The evaporation device includes: a magnetic adsorption layer and a thermosensitive layer located at a side of the magnetic adsorption layer, the thermosensitive layer is located between the magnetic adsorption layer and a side of the substrate far away from the mask, and the thermosensitive layer is configured to adjust a distance between the mask and the magnetic adsorption layer. FIG. 1 is a structural diagram illustrating an evaporation device provided by an embodiment of the present disclosure. By way of example, as illustrated in FIG. 1, the evaporation device can be used for evaporating a substrate 300, and a side of the substrate 300 is provided with a mask 400. The evaporation device can include: a magnetic adsorption layer 100 and a thermosensitive layer 200 located at a side of the magnetic adsorption layer 100, the thermosensitive layer 200 is located between the magnetic adsorption layer 100 and a side of the substrate 300 far away from the mask 400, and the thermosensitive layer 200 is configured to adjust a distance between the mask 400 and the magnetic adsorption layer 100.

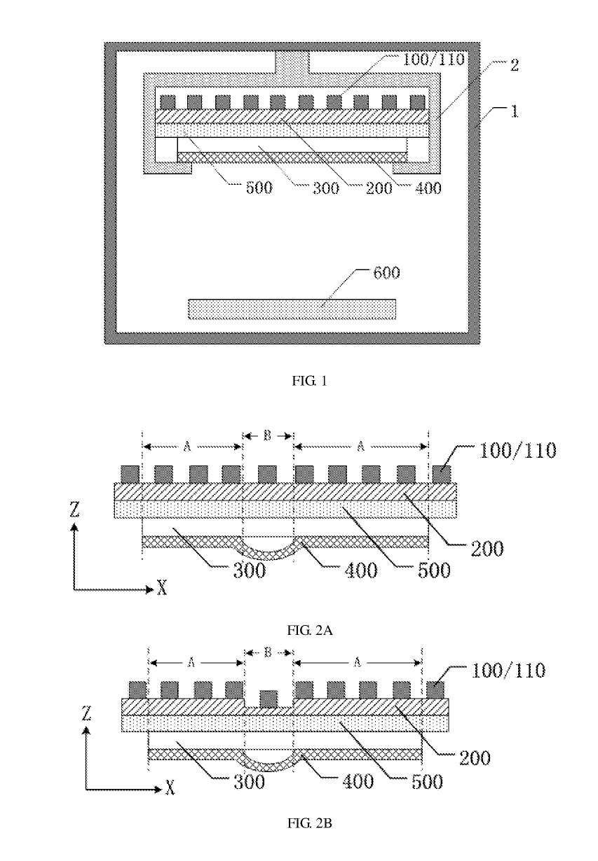

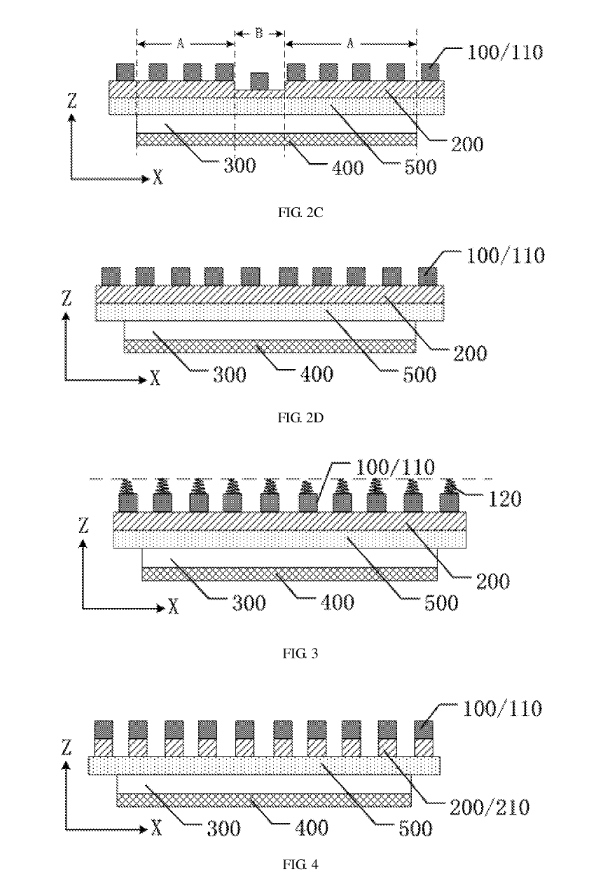

During an evaporation process, the substrate 300 to be evaporated is mounted on a side of the thermosensitive layer 200 far away from the magnetic adsorption layer 100. For example, a side of the substrate 300 far away from the magnetic adsorption layer 100 is provided with a mask 400. A magnetic adsorption force can be generated between the magnetic adsorption layer 100 and the mask 400. The magnetic adsorption force allows the mask 400 to be attached onto the substrate 300 which then can be evaporated through the mask 400. When a wrinkle is occurred in a local area (e.g., an area B as illustrated in FIG. 2A) of the mask 400, the thermosensitive layer 200 can adjust a spaced distance between a portion of the magnetic adsorption layer 100 in the corresponding area and a portion of the mask 400 in the corresponding area, i.e., adjusting the magnetic adsorption there-between, so that the wrinkle on the mask 400 can be attached onto the substrate 300. Thus, the thermosensitive layer 200 allows for closely attaching the substrate 300 with the mask 400 to improve the evaporation precision of the substrate 300. As for explanations concerning the thermosensitive layer 200 adjusting a spaced distance between a portion of the magnetic adsorption layer 100 in the corresponding area and a portion of the mask 400 in the corresponding area, reference may be made to embodiments (e.g., embodiments as illustrated in FIGS. 2A-2D) below, without repeating herein.

For example, in at least one embodiment of the present disclosure, a material of preparing the mask 400 can include a metal material or a magnetic adsorption material. In at least one embodiment of the present disclosure, the material of preparing the mask 400 is not particularly limited, as long as a magnetic adsorption force can be generated between the mask 400 and the magnetic adsorption layer 100.

For example, in at least one embodiment of the present disclosure, the evaporation device can further include an evaporation source which can be located at a side of the thermosensitive layer far away from the magnetic adsorption layer and be spaced from the thermosensitive layer by a predetermined distance. The evaporation source is configured to receive an evaporation material. By way of example, as illustrated in FIG. 1, the evaporation device can further include an evaporation source 600. The evaporation source 600 can be located at a side of the thermosensitive layer 200 far away from the magnetic adsorption layer 100 and be spaced from the thermosensitive layer 200 by a predetermined distance. The evaporation source 600 can be configured to receive an evaporation material, and can be heated to evaporate the evaporation material. A magnitude of the predetermined distance between the evaporation source 600 and the thermosensitive layer 200 can be determined according to actual demands, without particularly limited in the present disclosure. For example, the evaporation process can include: heating the evaporation material in the evaporation source 600 so that an atom or a molecule of the evaporation material can be gasified and escaped to form a vapor stream; guiding the evaporation material in gaseous state onto the substrate 300 (by an effect of, for example, gravity, electric field or magnetic field) so that the evaporation material is condensed into a solid film and meanwhile releasing a certain amount of heat. The mask 400 can define a pattern of the solid film.

The type of the evaporation source 600 is not particularly limited in at least one embodiment of the present disclosure. For example, in at least one embodiment of the present disclosure, the evaporation source 600 can be a point-type evaporation source or a line-type evaporation source, etc.

For example, in at least one embodiment of the present disclosure, a location of the evaporation source with respect to the substrate to be evaporated is not particularly limited but can be selected according to specific evaporation process. For example, in the direction of gravity, the evaporation source can be located above the substrate to be evaporated, although the evaporation source can also be located beneath the substrate to be evaporated, as long as the mask is located between the evaporation source and the substrate to be evaporated.

For example, in at least one embodiment of the present disclosure, the evaporation device can further include a vacuum evaporation chamber 1, as illustrated in FIG. 1. The vacuum evaporation chamber 1 can receive, for example, the magnetic adsorption layer 100, the thermosensitive layer 200, the evaporation source 600, the substrate 300 to be evaporated, and the like; furthermore, structures such as the magnetic adsorption layer 100, the thermosensitive layer 200, the substrate 300 to be evaporated, and the mask 400 on the substrate 300 to be evaporated can be fixed inside the vacuum evaporation chamber 1 through a supporting part 2.

For example, in at least one embodiment of the present disclosure, FIGS. 2A-2D are process diagrams illustrating a working principle of the evaporation device illustrated in FIG. 1, i.e., illustrating partial structure of the evaporation device. As illustrated in FIGS. 2A-2D, the working principle for the evaporation device to improve the evaporation precision of the substrate 100 can include steps as below.

As illustrated in FIG. 2A, an evaporation device is provided, wherein the evaporation device is provided with a substrate 300, and the substrate 300 is provided with a mask 400. For example, a wrinkle is occurred in an area B of the mask 400 and the area B is spaced from the substrate by a certain distance.

As illustrated in FIG. 2B, during the evaporation process, upon depositing an evaporation material onto the substrate 300 or the mask 400, the evaporation material releases heat which is directly diffused onto the substrate 300 or is transferred onto the substrate 300 through the mask 400 to raise a temperature of the substrate 300; moreover, the heat is also transferred onto the thermosensitive layer 200. When a wrinkle is occurred in the area B of the mask 400, the heat of the mask 400 in this area B will not be transferred onto the substrate 300, which decreases a heat conductivity of area B so that a temperature of the substrate 300 in area B is lower than that of the substrate 300 in area A. Correspondingly, a temperature of the thermosensitive layer 200 in area B is lower than that of the thermosensitive layer 200 in area A. As a result, in a direction perpendicular to a plane of the thermosensitive layer 200, i.e., in the Z direction (e.g., a direction perpendicular to a plane of the substrate 300), a thickness of the thermosensitive layer 200 in area B is smaller than that of the thermosensitive layer 200 in area A.

As illustrated in FIG. 2C, the thickness of the thermosensitive layer 200 in area B is reduced with respect to the thickness of the thermosensitive layer 200 in area A, which increases a magnetic adsorption force between the magnetic adsorption layer 100 in area B and the mask 400 in area B. In this way, the magnetic adsorption layer 100 in area B allows the mask 400 in area B to be attached onto the substrate 300 by using the magnetic adsorption force, so as to eliminate the issue of wrinkle on the mask 400.

As illustrated in FIG. 2D, after the mask 400 in area B is attached onto the substrate 300, a temperature of the substrate 300 in area B is raised, i.e., a temperature of the thermosensitive layer 200 in area B is also raised. When the temperature of the thermosensitive layer 200 in area B is equal to or close to the temperature of the thermosensitive layer 200 in area A, the thickness of the thermosensitive layer 200 in area B is equal to the thickness of the thermosensitive layer 200 in area A, along the Z direction.

In at least one embodiment of the present disclosure, a thermal expansion coefficient of the thermosensitive layer 200 is not particularly limited, as long as the thermosensitive layer 200 can adjust the distance between the magnetic adsorption layer 100 and the mask 400 through a change of temperature. For example, in at least one embodiment of the present disclosure, a range of linear expansion coefficient of the thermosensitive layer 200 includes about 10⁻⁵-10⁻³ m/degree.

In at least one embodiment of the present disclosure, the thermosensitive layer 200 has a certain thickness to adjust the distance between the magnetic adsorption layer 100 and the mask 400. For example, in at least one embodiment of the present disclosure, as illustrated in FIG. 1, in a direction perpendicular to a plane of the magnetic adsorption layer 100, a thickness range of the thermosensitive layer 200 includes about 1 mm˜10 cm. An excessively greater or smaller thickness of the thermosensitive layer 200 may go against its adjusting function in the evaporation device. For another example, a thickness range of the thermosensitive layer 200 can include about 1 cm˜5 cm. It should be explained that, the above-mentioned thickness range of the thermosensitive layer 200 refers to reference value under a normal temperature (e.g., 25° C.)

It should be explained that, in at least one embodiment of the present disclosure, specific structure of the magnetic adsorption layer is not particularly limited, as long as a shape of the magnetic adsorption layer can be changed with the thickness of the thermosensitive layer. For example, in some embodiments of the present disclosure, the magnetic adsorption layer can be configured as a flexible layer including a magnetic material. For example, in other embodiments of the present disclosure, the magnetic adsorption layer can include a plurality of magnetic adsorption units arranged in an array.

For example, in at least one embodiment of the present disclosure, as illustrated in FIGS. 1 and 2A-2D, the magnetic adsorption layer 100 can include a plurality of magnetic adsorption units 110 arranged in an array. The magnetic adsorption layer 100 is configured to include a plurality of magnetic adsorption units 110, so that during a deformation process of the thermosensitive layer 200 (e.g., when the thickness is changed), adjacent magnetic adsorption units 110 would not interference with each other, which improves a sensitivity of the evaporation device. For example, as illustrated in FIG. 2C, when the thickness of the thermosensitive layer 200 in area B is reduced, the magnetic adsorption unit 110 in area B will also be moved, without any interference from the magnetic adsorption unit 110 in area A close to area B.

For example, in at least one embodiment of the present disclosure, as illustrated in FIGS. 1 and 2A-2D, each of the magnetic adsorption units 110 can be mounted to be perpendicular to a plane of the magnetic adsorption layer 100. This facilitates moving the magnetic adsorption unit 110 when the thermosensitive layer 200 is deformed; i.e., this facilitates moving the magnetic adsorption unit upwards in the Z direction.

In at least one embodiment of the present disclosure, a mounting manner of the magnetic adsorption units is not particularly limited. For example, in at least one embodiment of the present disclosure, each of the magnetic adsorption units is mounted through an elastic component. FIG. 3 is a cross-sectional view illustrating another evaporation device provided by an embodiment of the present disclosure, i.e., illustrating partial structure of the evaporation device. By way of example, as illustrated in FIG. 3, each of the magnetic adsorption units 110 can be mounted on a mounting surface (e.g., the dotted line in FIG. 3) through an elastic component 120. The elastic component 120 can provide the magnetic adsorption unit 110 with a restoring force to move the magnetic adsorption unit 110. The elastic component 120 can be, for example, a compression spring.

For example, in at least one embodiment of the present disclosure, the magnetic adsorption unit 110 can be a permanent magnet or an electromagnet. In at least one embodiment of the present disclosure, a specific structure of the magnetic adsorption unit 110 is not particularly limited, as long as a magnetic adsorption force can be generated between the magnetic adsorption unit 110 and the mask 400.

In at least one embodiment of the present disclosure, a specific structure of the thermosensitive layer 200 is not particularly limited. For example, in some embodiments of the present disclosure, the thermosensitive layer can be configured as an integrally formed flexible layer. It should be explained that, a deformation precision of the thermosensitive layer may affect a mobile precision of the magnetic adsorption layer (e.g., the magnetic adsorption unit). In the case where the thermosensitive layer is an integrally formed one, portions with different deformation amount in the thermosensitive layer can be interfered with each other and hence to affect the deformation precision of the thermosensitive layer. For example, in other embodiments of the present disclosure, the thermosensitive layer can include a plurality of thermosensitive units arranged in an array, and each of the thermosensitive units is corresponding to one or more of the magnetic adsorption units. In this way, thermosensitive units with different deformation amounts in the thermosensitive layer will not be interfered with each other, thereby improving the deformation precision of the thermosensitive layer.

For example, in at least one embodiment of the present disclosure, FIG. 4 is a cross-sectional view illustrating another evaporation device provided by an embodiment of the present disclosure, i.e., illustrating partial structure of the evaporation device. As illustrated in FIG. 4, the thermosensitive layer 200 can include a plurality of thermosensitive units 210 arranged in an array, and each of the thermosensitive units 210 is corresponding to one or more of the magnetic adsorption units 110. During a deformation process of the thermosensitive layer 200 (e.g., when the thickness is changed) as illustrated in FIG. 2C, a deformation of the thermosensitive layer 200 in area A can interfere a deformation of the thermosensitive layer 200 in area B, which affects a sensitivity of removing the wrinkle on the mask 400 by the evaporation device. The thermosensitive layer 200 illustrated in FIG. 4 is configured to include a plurality of thermosensitive units 210, and adjacent thermosensitive units 210 will not be interfered with each other; in this way, the above-mentioned problem is solved, and the performance of the evaporation device is improved.

For example, in at least one embodiment of the present disclosure, as illustrated in FIGS. 1-4, the evaporation device can further include a cooling layer 500 disposed at a side of the magnetic adsorption layer 100 facing the thermosensitive layer 200. During the operation of the evaporation device, the cooling layer 500 can transfer the heat generated in the substrate 300, so as to avoid an excessively higher temperature of the substrate 300. For example, the cooling layer 500 can be provided with a plurality of guiding pipes to which a cooling liquid such as water is supplied.

In at least one embodiment of the present disclosure, a location of the cooling layer 500 can be determined according to actual demands, without particularly limited herein. Hereinafter, several arrangement locations of the cooling layer 500 will be described through several embodiments.

For example, in at least one embodiment of the present disclosure, FIG. 5 is a cross-sectional view illustrating another evaporation device provided by an embodiment of the present disclosure, i.e., illustrating partial structure of the evaporation device. For example, as illustrated in FIG. 5, the cooling layer 500 in the embodiment of the present disclosure has one side located on a side of the thermosensitive layer 200 far away from the magnetic adsorption layer 100, and the other side configured to face towards the substrate 300 to be evaporated; that is, the cooling layer 500 can be located between the thermosensitive layer 200 and the substrate 300.

For example, in at least one embodiment of the present disclosure, as illustrated in FIG. 5, the evaporation device can further include a limiting layer 700 configured to limit the magnetic adsorption layer 100, and the limiting layer 700 can be located between the magnetic adsorption layer 100 and the thermosensitive layer 200. For example, the limiting layer 700 can fix the magnetic adsorption layer 100 in a horizontal direction (the X direction) as illustrated in FIG. 5. For example, in the case where the magnetic adsorption layer 100 includes a plurality of magnetic adsorption units 110, the limiting layer 700 can be configured to limit each of the magnetic adsorption units 110, so as to adjust a distribution of magnetic field generated by the magnetic adsorption layer 100. For example, in at least one embodiment of the present disclosure, during a deformation process of the thermosensitive layer 200 as illustrated in FIG. 2C, the limiting layer 700 can be configured as a flexible layer in order to prevent the limiting layer 700 from interfering a movement of the magnetic adsorption layer 100 (e.g., a movement of the magnetic adsorption unit 110 in area B).

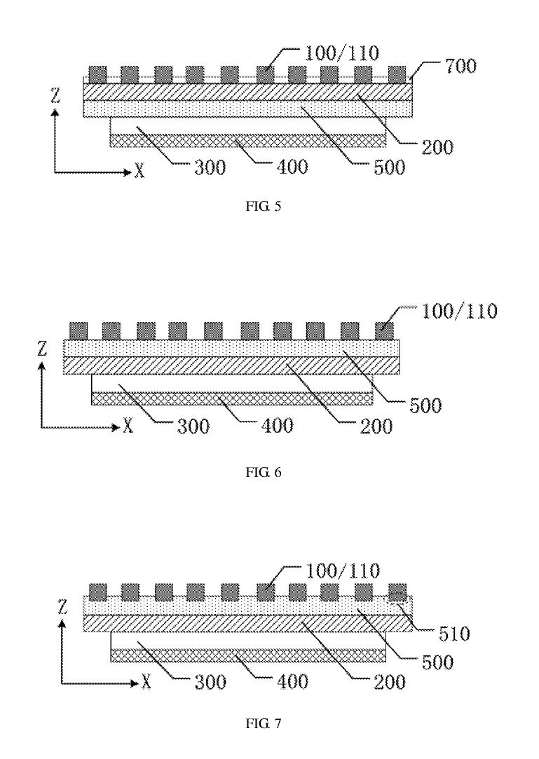

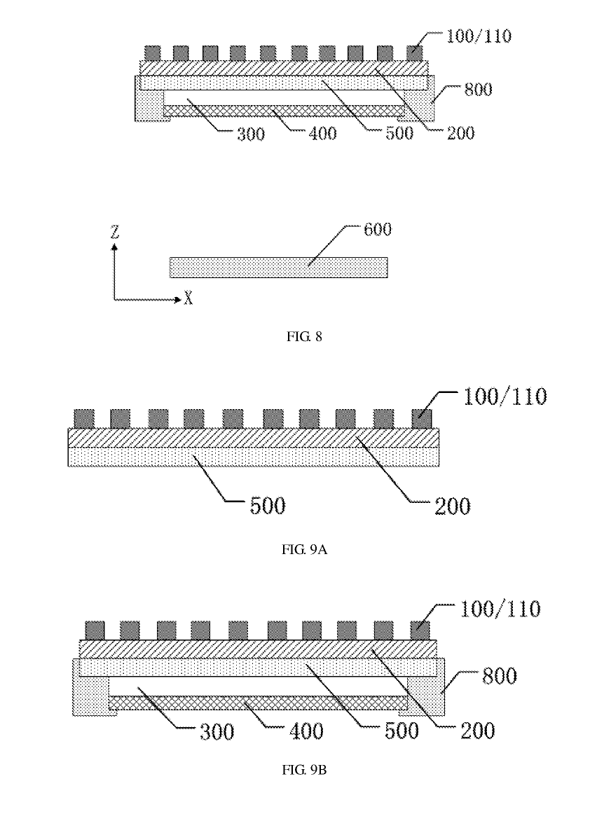

For example, in at least one embodiment of the present disclosure, FIG. 6 is a cross-sectional view illustrating another evaporation device provided by an embodiment of the present disclosure, i.e., illustrating partial structure of the evaporation device. As illustrated in FIG. 6, the cooling layer 500 in the evaporation device is disposed between the magnetic adsorption layer 100 and the thermosensitive layer 200. As compared with the location of the cooling layer 500 in the evaporation device as illustrated in FIG. 5, the thermosensitive layer 200 as illustrated in FIG. 6 is closer to the substrate 300. For example, the thermosensitive layer 200 can also be directly contacted with the substrate 300. In such case, the thermosensitive layer 200 is more sensitive to the change of temperature in the substrate 300. In order to prevent the cooling layer 500 from interfering the movement of the magnetic adsorption layer 100 as illustrated in FIG. 2C (e.g., the movement of the magnetic adsorption unit 110 in area B), the cooling layer 500 can be configured as a flexible cooling layer.

For example, in at least one embodiment of the present disclosure, FIG. 7 is a cross-sectional view illustrating another evaporation device provided by an embodiment of the present disclosure, i.e., illustrating partial structure of the evaporation device. As illustrated in FIG. 7, a surface of the cooling layer 500 far away from the thermosensitive layer 200 is provided with a recess 510 for limiting the magnetic adsorption layer 100. The recess 510 can fix the magnetic adsorption layer 100 in a horizontal direction (the X direction) as illustrated in FIG. 7. For example, in the case where the magnetic adsorption layer 100 includes a plurality of magnetic adsorption units 110, the recess 510 can be configured to limit each of the magnetic adsorption units 110, so as to adjust a distribution of magnetic field generated by the magnetic adsorption layer 100.

For example, in at least one embodiment of the present disclosure, FIG. 8 is a cross-sectional view illustrating another evaporation device provided by an embodiment of the present disclosure, i.e., illustrating partial structure of the evaporation device. As illustrated in FIG. 8, the evaporation device can further include a mounting part 800. The mounting part 800 is located between the thermosensitive layer 200 and the evaporation source 600, and is configured to allow the substrate 300 to be evaporated and the mask 400 for evaporation to be mounted sequentially in this order. For example, the mounting part 800 can fix and limit the substrate 300, and the mounting part 800 can align the mask 400 with the substrate 300, so as to ensure an evaporation precision.

At least one embodiment of the present disclosure provides a manufacturing apparatus of a display device. The manufacturing apparatus can include the evaporation device described in any of the embodiments above. For example, the manufacturing apparatus can further include structures such as a vacuum pump and transmission pipe of evaporation material.

In at least one embodiment of the present disclosure, an application field of the manufacturing apparatus is not particularly limited. For example, the manufacturing apparatus can be applied in a manufacturing process of a display device. For example, the manufacturing apparatus can be applied to manufacturing structures such as an organic light-emitting device in an organic light-emitting diode (OLED) display panel, for example, to manufacture a cathode, an anode and a light-emitting layer located between the cathode and the anode in the organic light-emitting device.

At least one embodiment of the present disclosure provides an evaporation method of an evaporation device, including: sequentially mounting a substrate to be evaporated and a mask covering the substrate at a side of a thermosensitive layer far away form a magnetic adsorption layer; heating an evaporation material at a side of the substrate far away from the thermosensitive layer to evaporate the substrate through the mask. As for the specific structure of the evaporation device, reference may be made to related contents in the preceding embodiments (embodiments related to the evaporation device), without repeating herein.

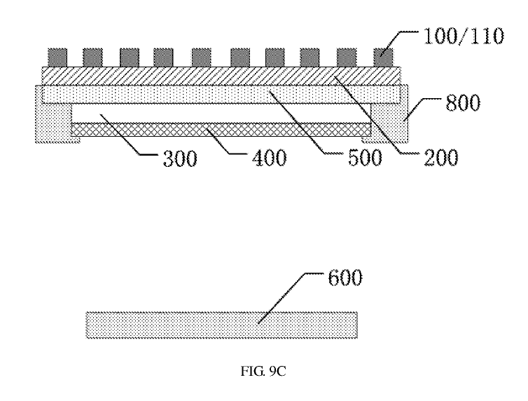

In order for convenience of explaining an evaporation method of an evaporation device in the embodiments of the present disclosure, at least one example is described in details. FIGS. 9A-9C are process diagrams illustrating an evaporation method of an evaporation device provided by an embodiment of the present disclosure. As illustrated in FIGS. 9A-9C, an evaporation method of an evaporation device in an example of the present disclosure includes steps as below.

As illustrated in FIG. 9A, providing an evaporation device. The evaporation device includes a magnetic adsorption layer 100, a cooling plate 500 and a thermosensitive layer 200 located between the magnetic adsorption layer 100 and the cooling plate 500. As for the arrangement manner and the specific structures of the magnetic adsorption layer 100, the cooling plate 500 and the thermosensitive layer 200, reference may be made to related contents in the preceding embodiments, without repeating herein.

As illustrated in FIG. 9B, mounting a mask 400 on the substrate 300 through a mounting part 800, and fixing the substrate 300 mounted with the mask 400 on the evaporation device. The substrate 300 is located at a side of the thermosensitive layer 200 far away from the magnetic adsorption layer 100, and the mask 400 is located at a side of the substrate 300 far away from the magnetic adsorption layer 100.

As illustrated in FIG. 9C, providing an evaporation source 600, and heating an evaporation material in the evaporation source 600 to deposit an evaporation pattern of the evaporation material on a side surface of the substrate 300 far away from the thermosensitive layer 200 by using the mask 400. As for the arrangement manner of the evaporation source 600, reference may be made to related contents in the preceding embodiments, without repeating herein.

At least one embodiment of the present disclosure provides an evaporation device and a manufacturing apparatus of a display device, and possesses at least one of the following beneficial effects.

(1) At least one embodiment of the present disclosure provides an evaporation device in which a thermosensitive layer can adjust its thickness according to a change in temperature so as to adjust a spaced distance between a magnetic adsorption layer and a mask, thereby mitigating or eliminating the issue of wrinkle in the mask.

(2) In at least one embodiment of the present disclosure, the evaporation device can adjust a spaced distance between the mask and the magnetic adsorption layer in real time during an evaporation process, so as to ensure the mask and the substrate to be closely attached with each other and hence to improve an evaporation yield of the substrate.

The following statements should be noted:

(1) The accompanying drawings involve only the structure(s) in connection with the embodiment(s) of the present disclosure, and other structure(s) can be referred to common design(s).

(2) For the purpose of clarity only, in accompanying drawings for illustrating the embodiment(s) of the present disclosure, the thickness a layer or area may be enlarged or narrowed, that is, the drawings are not drawn in a real scale.

(3) In case of no conflict, features in one embodiment or in different embodiments can be combined.

The above are merely specific implementations of the present disclosure without limiting the protection scope of the present disclosure thereto. The protection scope of the present disclosure should be based on the protection scope of the appended claims.

1. An evaporation device for evaporating a substrate, a side of the substrate being provided with a mask,
the evaporation device comprising:
a magnetic adsorption layer; and
a thermosensitive layer located at a side of the magnetic adsorption layer,
wherein the thermosensitive layer is located between the magnetic adsorption layer and a side of the substrate far away from the mask, and the thermosensitive layer is configured to adjust a distance between the mask and the magnetic adsorption layer.

2. The evaporation device according to claim 1, wherein
a range of linear expansion coefficient of the thermosensitive layer comprises about 10⁻⁵-10⁻³ m/degree.

3. The evaporation device according to claim 1, wherein
in a direction perpendicular to a plane of the magnetic adsorption layer, a thickness range of the thermosensitive layer comprises about 1 mm˜10 cm.

4. The evaporation device according to claim 1, wherein the magnetic adsorption layer comprises a plurality of magnetic adsorption units arranged in an array.

5. The evaporation device according to claim 4, wherein each of the magnetic adsorption units is mounted through an elastic component.

6. The evaporation device according to claim 4, wherein
the thermosensitive layer comprises a plurality of thermosensitive units arranged in a array, and each of the thermosensitive units is corresponding to one or more of the magnetic adsorption units.

7. The evaporation device according to claim 1, further comprising a cooling layer located at a side of the magnetic adsorption layer facing the thermosensitive layer.

8. The evaporation device according to claim 7, wherein
one side of the cooling layer is located on a side of the thermosensitive layer far away from the magnetic adsorption layer, and the other side of the cooling layer is mounted with the substrate to be evaporated.

9. The evaporation device according to claim 8, further comprising: a limiting layer configured to limit the magnetic adsorption layer;
wherein the limiting layer is a flexible layer, and the limiting layer is located between the thermosensitive layer and the magnetic adsorption layer.

10. The evaporation device according to claim 7, wherein
the cooling layer is located between the magnetic adsorption layer and the thermosensitive layer, and the cooling layer is a flexible cooling layer.

11. The evaporation device according to claim 10, wherein
a surface of the cooling layer far away from the thermosensitive layer is provided with a recess configured to limit the magnetic adsorption layer.

12. The evaporation device according to claim 1, further comprising an evaporation source, the evaporation source is located at a side of the thermosensitive layer far away from the magnetic adsorption layer and is spaced from the thermosensitive layer by a predetermined distance,
wherein the evaporation source is configured to receive a material to be evaporated.

13. The evaporation device according to claim 12, further comprising a mounting part, wherein the mounting part is located between the thermosensitive layer and the evaporation source and is configured to allow the substrate and the mask to be mounted thereon.

14. A manufacturing apparatus of a display device, comprising an evaporation device for evaporating a substrate, a side of the substrate being provided with a mask,
the evaporation device comprising:
a magnetic adsorption layer; and
a thermosensitive layer located at a side of the magnetic adsorption layer,
wherein the thermosensitive layer is located between the magnetic adsorption layer and a side of the substrate far away from the mask and the theme sensitive layer is configured to adjust a distance between the mask and the magnetic adsorption layer.

15. The manufacturing apparatus according to claim 14, wherein the magnetic adsorption layer comprises a plurality of magnetic adsorption units arranged in an array.

16. The manufacturing apparatus according to claim 15, wherein each of the magnetic adsorption units is mounted through an elastic component.

17. The manufacturing apparatus according to claim 15, wherein
the thermosensitive layer comprises a plurality of thermosensitive units arranged in a array, and each of the thermosensitive units is corresponding to one or more of the magnetic adsorption units.

18. The manufacturing apparatus according to claim 14, further comprising a cooling layer located at a side of the magnetic adsorption layer facing the thermosensitive layer.

19. The manufacturing apparatus according to claim 18, wherein
one side of the cooling layer is located on a side of the thermosensitive layer far away from the magnetic adsorption layer, and the other side of the cooling layer is mounted with the substrate to be evaporated.

20. The manufacturing apparatus according to claim 19, further comprising: a limiting layer configured to limit the magnetic adsorption layer;
wherein the limiting layer is a flexible layer, and the limiting layer is located between the thermosensitive layer and the magnetic adsorption layer.
